(19) United States
(12) Patent Application Publication
(10) Pub. No.: US 2016/0095251 A1
(43) Pub. Date: Mar. 31, 2016

(54) HEAT DISSIPATION DEVICE AND METHOD FOR MANUFACTURING THE SAME

(71) Applicant: Foxconn Technology Co., Ltd., New Taipei (TW)

(72) Inventors: YU-CHING LIN, New Taipei (TW); JUI-WEN HUNG, New Taipei (TW)

(21) Appl. No.: 14/526,272

(22) Filed: Oct. 28, 2014

(30) Foreign Application Priority Data
Sep. 30, 2014 (TW) 103133897

(51) Int. Cl. H05K 7/20; B23K 26/21; B23P 15/26

(52) U.S. Cl. CPC H05K 7/20154; B23P 15/26; B23K 26/21; H05K 7/20172

(57) ABSTRACT

The heat dissipation device includes a heat absorbing base and a fan mounted on the heat absorbing base. The heat absorbing base includes a first surface configured for contacting a heat generating element, and a second surface opposite to the first surface. The fan includes a bearing and a rotor pivotally coupled with the bearing. The bearing is mounted on the second surface of the heat absorbing base.

### FIELD

The subject matter herein generally relates to a heat dissipation device having a heat absorbing base and a fan directly mounted on the heat absorbing base.

### BACKGROUND

A typical heat dissipation device includes a heat absorbing base, a heat-sink with plurality of fins mounted on the base, and a fan fixed onto the fins of the heat-sink by hooks or screws. The configuration of the typical heat dissipation is complex, and the manufacturing or assembling process become complicated.

### BRIEF DESCRIPTION OF THE DRAWINGS

Implementations of the present technology will now be described, by way of example only, with reference to the attached figures.

FIG. 1 is a perspective view of a heat dissipation device in accordance with a first embodiment of the present disclosure.

FIG. 2 is an exploded, isometric view of the heat dissipation device of FIG. 1.

FIG. 3 is an exploded, isometric view of the heat dissipation device of FIG. 2 from a different angle.

FIG. 4 is a perspective view of a heat dissipation device in accordance with a second embodiment of the present disclosure.

FIG. 5 is an exploded, isometric view of the heat dissipation device of FIG. 4.

FIG. 6 is an exploded, isometric view of the heat dissipation device of FIG. 5 from a different angle.

FIG. 7 is a cross-sectional view of the heat dissipation device of FIG. 4, taken along the line VII-VII.

FIG. 8 is an assembled view of the heat dissipation device of FIG. 4 mounted on a circuit board.

FIG. 9 is a perspective view of a heat absorbing plate for manufacturing a heat dissipation device.

FIG. 10 is a top plan view of the heat absorbing plate of FIG. 9 with four notches in four corners.

FIG. 11 is a top plan view of another heat absorbing plate for manufacturing a heat dissipation device.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

The present disclosure is described in relation to a heat dissipation device and a method for manufacturing the heat dissipation device.

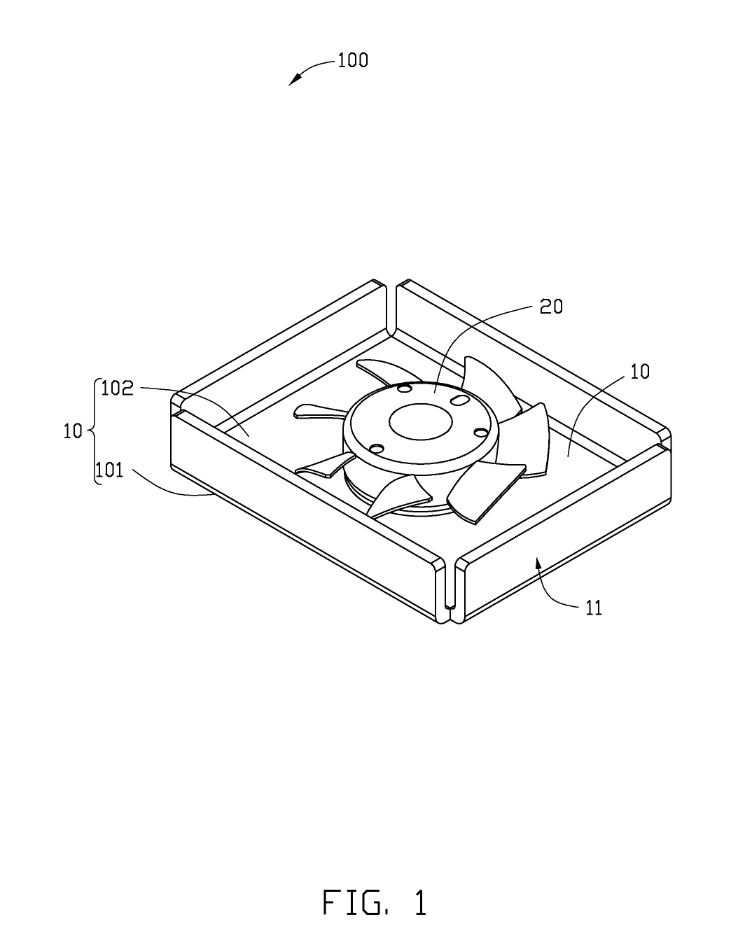

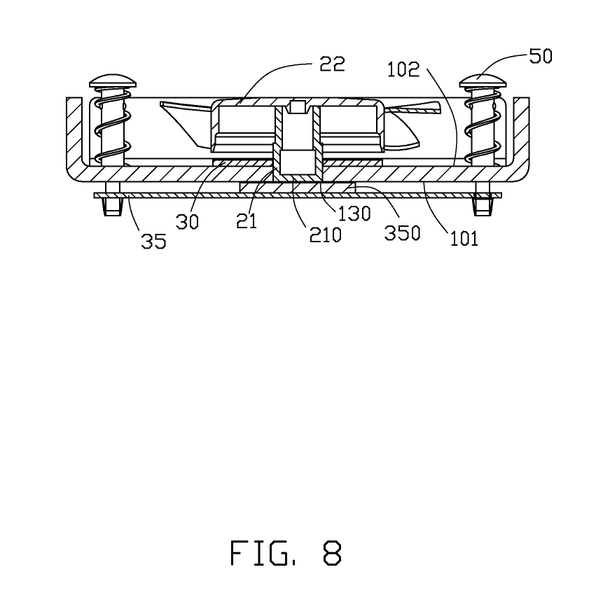

FIGS. 1-3 illustrate a heat dissipation device in accordance with a first embodiment of the present disclosure. The heat dissipation device 100 includes a heat absorbing base 10 and a fan 20 mounted on the heat absorbing base 10. The heat absorbing base 10 includes a first surface 101 configured for contacting a heat generating element 350 (shown in FIG. 8), and a second surface 102 opposite to the first surface 101. The fan 20 includes a bearing 21 and a rotor 22 pivotally coupled with the bearing 21. The bearing 21 is directly mounted on the second surface 102 of the heat absorbing base 10.

The heat absorbing base 10 may be made of copper, aluminum, or an alloy of copper and aluminum. The heat absorbing base 10 is a flat plate, such that the first surface 101 and the second surface 102 are flat.

The heat absorbing base 10 further includes a side plate 11. The side plate 11 upwardly extends along peripheral sides of the heat absorbing base 10. In at least one embodiment, the side plate 11 is formed with the heat absorbing base 10 as a single piece, and bends upwardly from the peripheral sides of the heat absorbing base 10.

The side plate 11 surrounds the fan 20 to receive the fan 20 in a receiving space defined by the side plate 11 and the second surface 102 of the heat absorbing base 10. Preferably, a height of the side plates 11 is larger than that of the fan 20. The side plate 11 is perpendicular to the second surface 102 of the heat absorbing base 10. Alternatively, the side plates 11 may extend upwardly and slantwise in relation to the heat absorbing base 10.

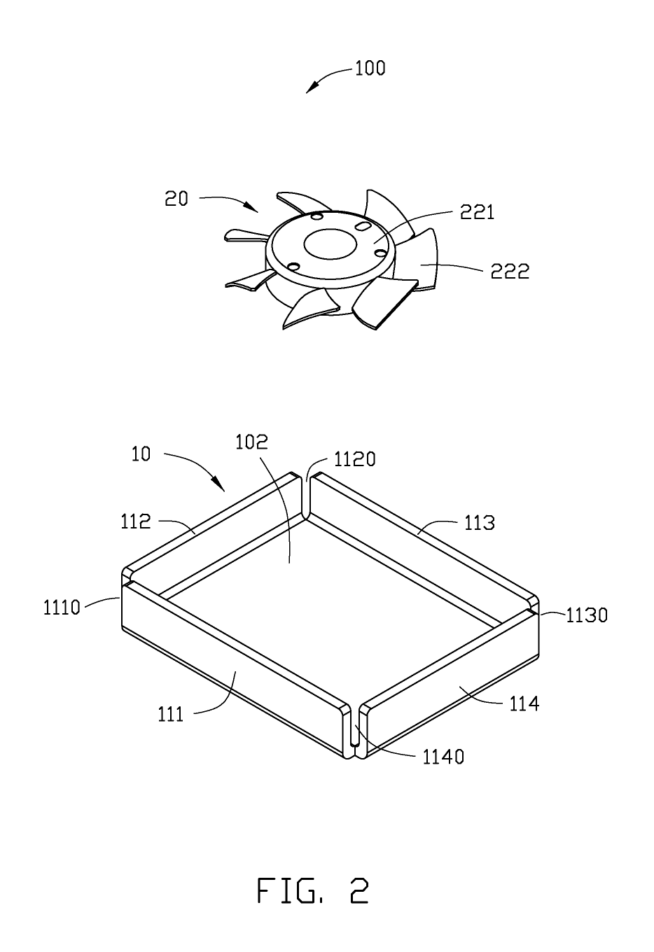

Referring to FIG. 2, at least one air channel may be defined through the side plate 11. In at least one embodiment, the side plate 11 includes a first side plate 111, a second side plate 112, a third side plate 113 and a fourth side plate 114. The first side plate 111, the second side plate 112, the third side plate 113 and the fourth side plate 114 are spaced from each other, and respectively extend upwardly along peripheral sides of the heat absorbing base 10. The second side plate 112 and the fourth side plate 114 are located at opposite sides of the first side plate 111, and are respectively spaced from the first side plate 111. The third side plate 113 is arranged facing with the first side plate 111. The third side plate 113 is spaced from the second side plate 112, and is spaced from the fourth side plate 114.

A first air channel 1110 is defined between the first side plate 111 and the second side plate 112. A second air channel 1120 is defined between the second side plate 112 and the third side plate 113. A third air channel 1130 is defined between the third side plate 113 and the fourth side plate 114. A fourth air channel 1140 is defined between the fourth side plate 114 and the first side plate 111. In at least one embodiment, the first air channel 1110 is aligned with the third air channel 1130, and the second air channel 1120 is aligned with the fourth air channel 1140.

The fan 20 is mounted on the second surface 102 of the heat absorbing base 10. Preferably, the fan 20 is mounted in a central portion of the heat absorbing base 10. The fan 20 can be mounted on the heat absorbing base 10 by laser welding technology. Alternatively, the fan 20 may be riveted, welded or glued to the heat absorbing base 10.

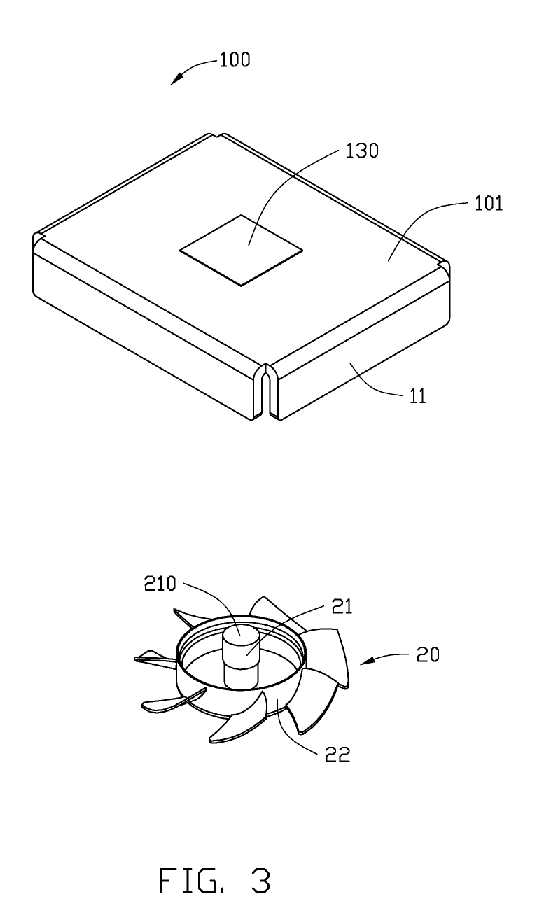

Referring to FIG. 3, a shaft hole is defined in a central portion of the bearing 21. The rotor 22 includes a hub 221, a plurality of blades 222 formed at an outer periphery of the hub 221, and a shaft outwardly extends from a central portion of the hub 221. The rotor 22 is pivotally coupled with the bearing 221 via the shaft hole and the shaft. A free end 210 of the bearing 21 far away from the hub 221 is directly mounted on the heat absorbing base 10. Preferably, the bearing 21 can be mounted on the heat absorbing base 10 by laser welding technology. Alternatively, the fan 20 may be riveted, welded or glued to the heat absorbing base 10.

Referring to FIG. 8, heat generated by the heat generating element 350 is conducted to the heat absorbing base 10. The fan 20 drives air toward the second surface 102 of the heat absorbing base 10 to dissipate the heat conducted to the heat absorbing base 10. The bearing 21 is directly mounted on the second surface 102 of the heat absorbing base 10 without any heat-sink, the configuration of the heat dissipation device 100 becomes simple, and the manufacturing process and the assembling process is simplified. In addition, when air is driven to the heat absorbing base 10 by the fan 20, the air is guided by the heat absorbing base 10 toward the air channels located at peripheral sides of the heat absorbing base 10. Such that, other electrical elements located near the heat generating element 350 may be cooled.

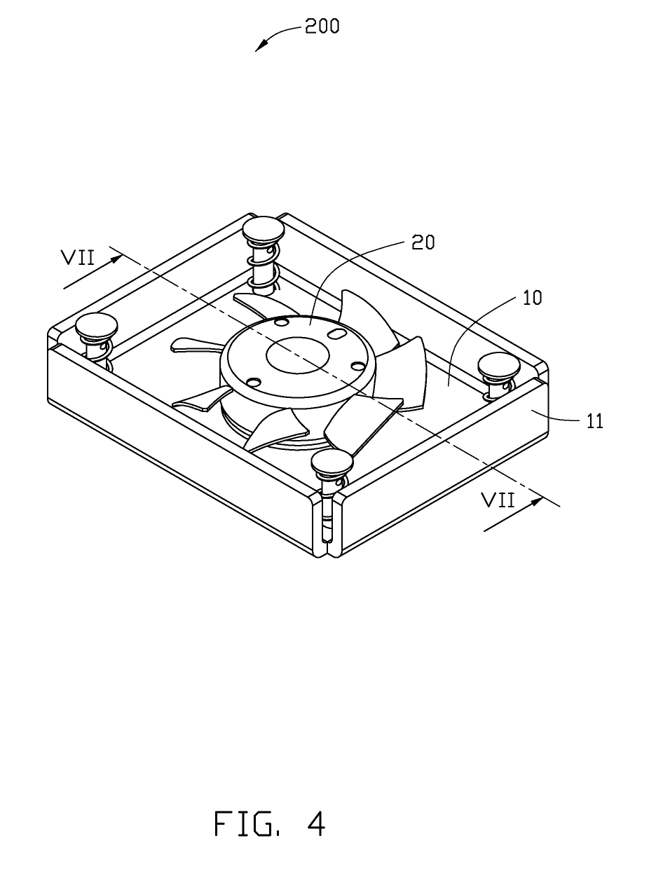

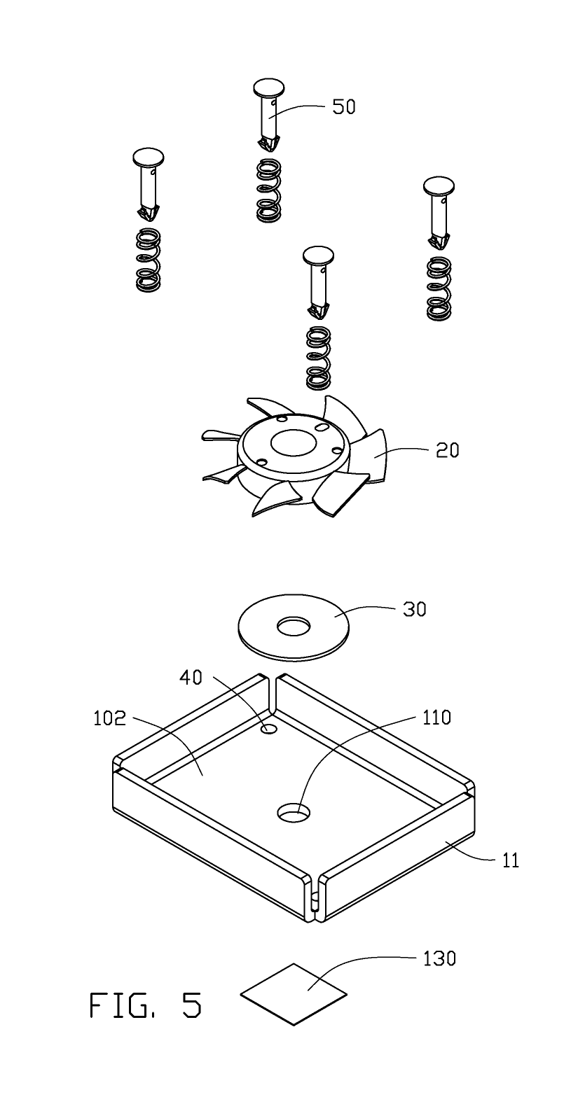

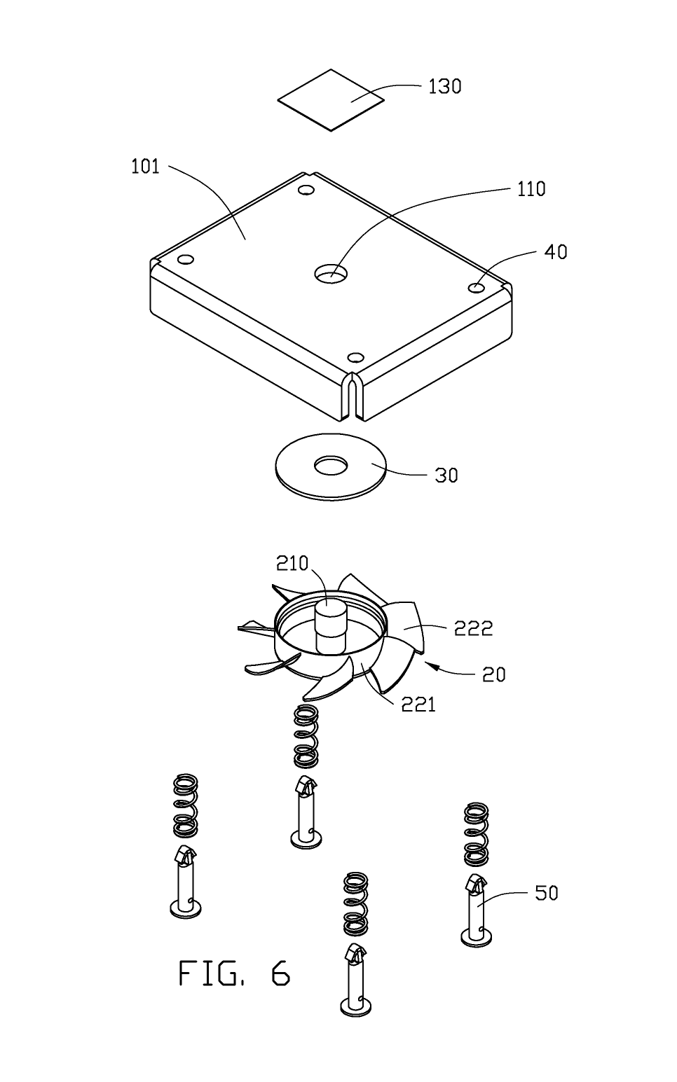

FIGS. 4-6 illustrate a heat dissipation device 200 in accordance with a second embodiment of the present disclosure.

A though hole 110 is defined in a central portion of the heat absorbing base 10. A heat absorbing sheet 130 is provided to attach to the first surface 101 of the heat absorbing base 10. The heat absorbing sheet 130 is corresponding with the though hole 110. The heat absorbing sheet 130 is configured to contact the heat generating element 350. A size of the heat absorbing sheet 130 is larger than that of the though hole 110. In at least one embodiment, the heat absorbing sheet 130 is rectangular.

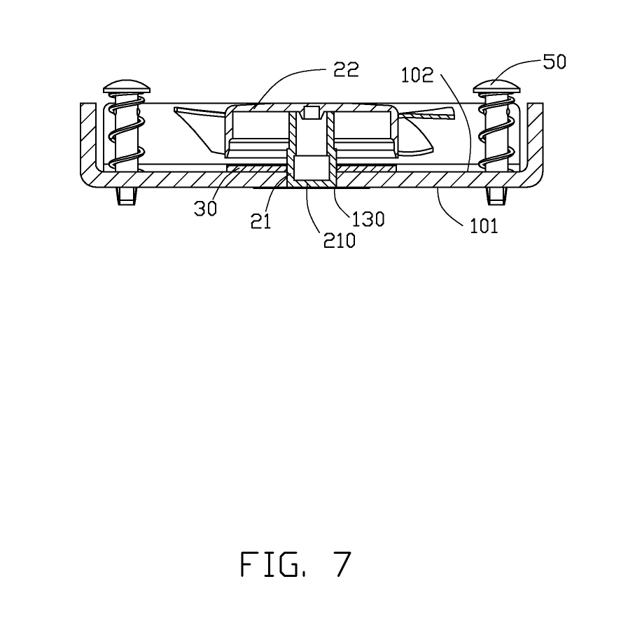

Also referring to FIG. 7, when assembling the heat dissipation device 200, the rotor 22 is pivotally coupled with the bearing 21. A free end 210 of the bearing 21 passes through the though hole 110, and abuts a top surface of the heat absorbing sheet 130. An outer end face of the free end 210 is coplanar with the first surface 101 of the heat absorbing base 10. In at least embodiment, the free end 210 of the bearing 21 is coupled with the heat absorbing sheet 130 by laser welding technology. Alternatively, the free end 210 of the bearing 21 may be riveted, welded or glued to the heat absorbing sheet 130.

In addition, a connecting plate 30 is located between the rotor 22 and the second surface 102 of the heat absorbing base 10. The connecting plate 30 is made of metallic material. The connecting plate 30 is ring-shaped. The connecting plate 30 is passed through by the bearing 21, and the connecting plate 30 engages with peripheral surfaces of the bearing 21. The connecting plate 30 is mounted on the heat absorbing base 10 by laser welding technology. Alternatively, the connecting plate 30 may be riveted, welded or glued to the heat absorbing base 10.

Referring to FIG. 8, the heat dissipation device 200 is fixed onto a circuit board 35. A plurality of fixing holes 40 are defined in the heat absorbing base 10. Fixing members 50 are corresponding with the fixing holes 40, and the fixing members 50 are configured to fix the heat dissipation device 200 to the circuit board 35. In at least one embodiment, the fixing holes 40 may be screw holes, and the fixing members 50 may be screws matching the screw holes.

The disclosure also relates a method for manufacturing the heat dissipation device.

Referring to FIGS. 1-3, the method of manufacturing a heat dissipation device includes providing a heat absorbing base 10, the heat absorbing base 10 includes a first surface 101 configured for contacting a heat generating element 350 and a second surface 102 opposite to the first surface 101.

The method further includes providing a fan 20 having a bearing 21 and a rotor 22 pivotally coupled with the bearing 21, and mounting the bearing 21 to the second surface 102 of the heat absorbing base 10. The bearing 21 may be mounted on the heat absorbing base 10 by laser welding technology.

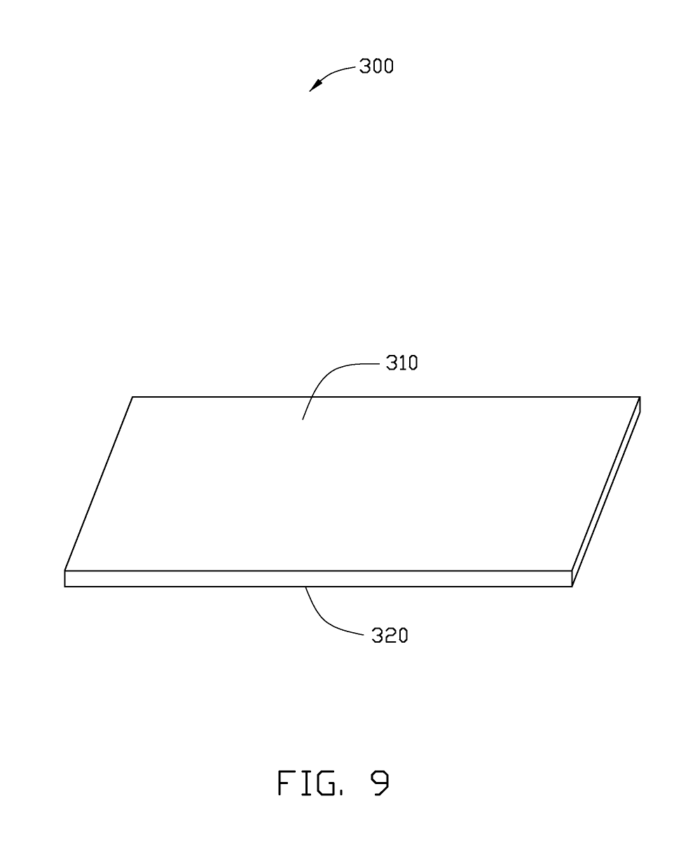

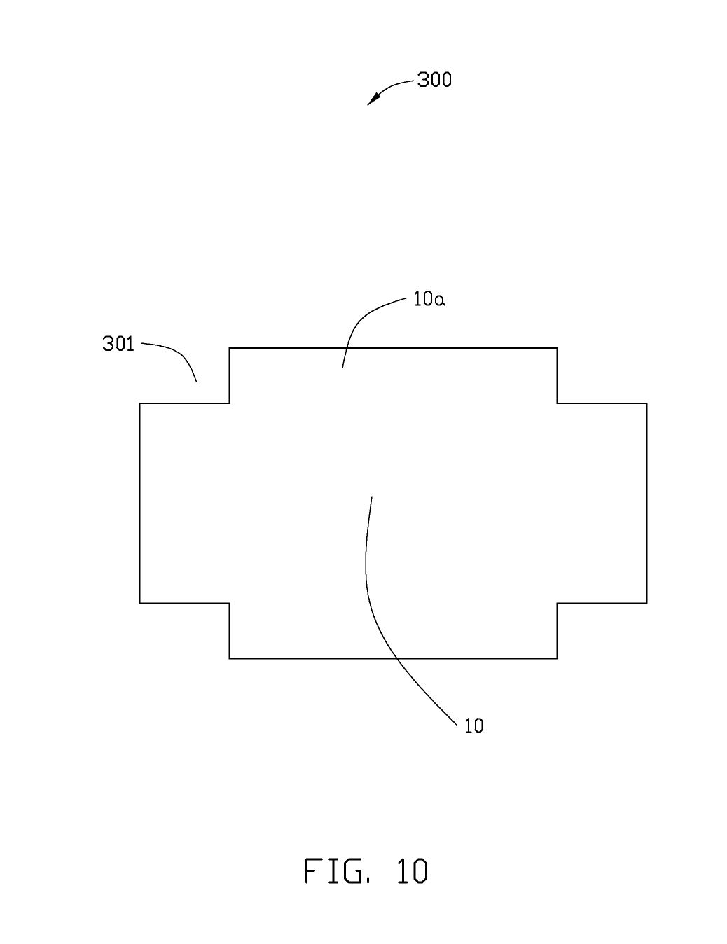

Referring to FIGS. 9-10, the disclosure also relates another method for manufacturing a heat dissipation device.

The method includes providing a heat absorbing plate 300, and forming a plurality of notches 301 in the edges of the heat absorbing plate 300 to form a heat dissipation base 10 and a plurality of flanges 10a.

The flanges 10a extends outwardly from a periphery of the heat absorbing base 10. The heat absorbing base 10 includes a first surface 101 configured to contact a heat generating element 350, and a second surface 102 opposite to the first surface 101. The flanges 10a are configured to surround the periphery of the fan 20. In at least one embodiment, the heat absorbing plate 300 is rectangular, and the number of the notches 301 is four. The notches 301 are located in four corners of the heat absorbing plate 300. The number of the flanges 10a is four. The notches 301 may be formed by punching the heat absorbing plate 300. The heat absorbing plate 300 is made of metallic material, such as copper, aluminum, or an alloy of copper and aluminum.

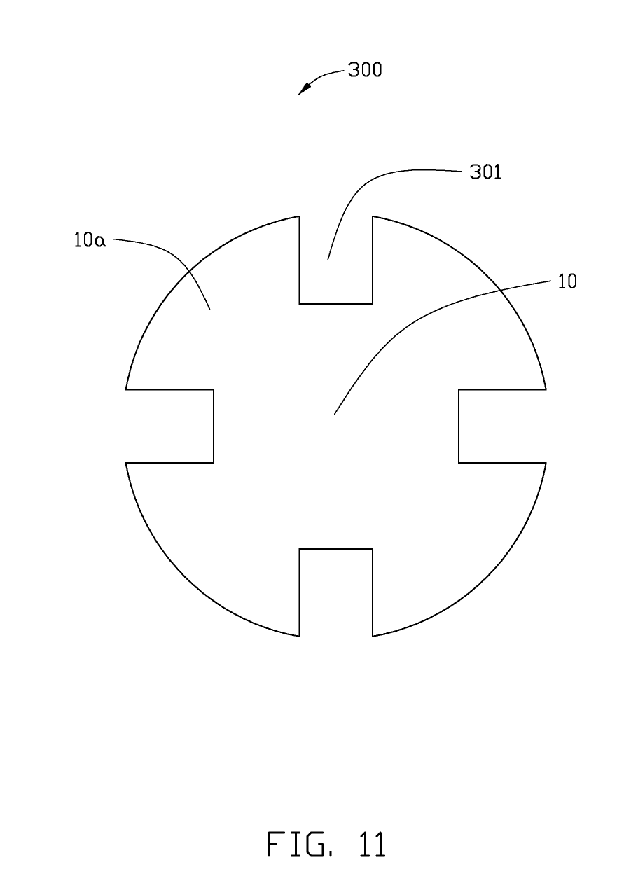

Alternatively, referring to FIG. 11, the heat absorbing plate 300 may be a circular plate. The notches 301 are defined to pass through the outer edges of the heat absorbing plate 300. Preferably, the notches 301 are equidistantly spaced from each other.

Referring to FIGS. 4-6, the method further includes bending the flanges 10a toward a same side of the heat absorbing base 10 to form a side plate 11. The side plates 11 and the heat absorbing base 10 corporately define a receiving space to receive a fan 20.

The method further includes providing a fan 20, and mounting the fan 20 on the heat absorbing base 10. The fan 20 includes a bearing 21 and a rotor 22 pivotally coupled with the bearing 21. A free end 210 of the bearing 21 is mounted onto the heat absorbing base 10. Preferably, the fan 20 is mounted in a central portion of the heat absorbing base 10.

Alternatively, the fan 20 may be mounted by the following process including defining a though hole 110 in the heat absorbing base 10, and providing a heat absorbing sheet 130 to attach to the second surface 102 of the heat absorbing base 10, and passing the free end 210 of the bearing 21 through the through hole 110 to connect with the heat absorbing sheet 130. In at least one embodiment, the free end 210 of the bearing 21 may be coupled with the heat absorbing sheet 130 by laser welding technology.

The embodiments shown and described above are only examples. Many details are often found in the art such as the other features of a heat dissipation device and a method for manufacturing the heat dissipation device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A heat dissipation device comprising:
a heat absorbing base comprising a first surface configured for contacting a heat generating element and a second surface opposite to the first surface; and
a fan directly mounted on the second surface of the heat absorbing base, the fan comprising a bearing and a rotor pivotally coupled with the bearing, the bearing being directly mounted onto the second surface of the heat absorbing base.

2. The heat dissipation device of claim 1 further comprising a side plate, wherein the side plate extends upwardly from peripheral sides of the heat dissipation base to surround the fan.

3. The heat dissipation device of claim 2, wherein at least an air channel is defined through the side plate.

4. The heat dissipation device of claim 2, wherein the side plate comprises a first side plate, a second side plate and a third side plate, the first side plate, the second side plate and the third side plate are spaced from each other.

5. The heat dissipation device of claim 4, wherein a first air channel is defined between the first side plate and the second side plate, a second air channel is defined between the second side plate and the third side plate, and a third air channel is defined between the third side plate and the first side plate.

6. The heat dissipation device of claim 4 further comprises a fourth side plate, the first side plate, the second side plate, the third side plate and the fourth side plate are spaced from each other, and respectively extends upwardly from peripheral sides of the heat absorbing base.

7. The heat dissipation device of claim 6, wherein a first air channel is defined between the first side plate and the second side plate, a second air channel is defined between the second side plate and the third side plate, a third air channel is defined between the third side plate and the fourth side plate, and the a fourth air channel is defined between the fourth side plate and the first side plate.

8. The heat dissipation device of claim 7, wherein the first air channel is aligned with the second air channel and the second air channel is aligned with the fourth air channel.

9. The heat dissipation device of claim 1, wherein a through hole is defined in the heat absorbing base, a free end of the bearing passes through the through hole to contact a heat absorbing sheet attached to the second surface of the heat absorbing base corresponding with the through hole.

10. The heat dissipation device of claim 9, wherein a connecting plate is located between the fan and the first surface of the heat absorbing base.

11. The heat dissipation device of claim 10, wherein the free end of the bearing pass through the connecting plate.

12. A method for manufacturing a heat dissipation device comprising:
providing a heat absorbing base comprising a first surface configured for contacting a heat generating element and a second surface opposite to the first surface; and
providing a fan having a bearing and a rotor pivotally coupled with the bearing, and mounting the bearing of the fan onto the second surface of the heat absorbing base.

13. The method of claim 12, wherein the bearing is laser welding to the heat dissipation base.

14. A method for manufacturing a heat dissipation device comprising:
providing a heat absorbing plate, and forming notches in the edges of the heat absorbing base to form a heat absorbing base and flanges extending outwardly from the heat absorbing base, the heat absorbing base comprising a first surface configured for contacting a heat generating element and a second surface opposite to the first surface;
bending the flanges toward a same side of the heat absorbing base to form a side plate configured for surrounding a fan;
providing a fan comprising a bearing and a rotor pivotally coupled with the bearing, and mounting the fan on the second surface of heat absorbing base.

15. The method of claim 14 further comprising defining a through hole in the heat absorbing base, and providing a heat absorbing sheet to attach to the second surface of the heat absorbing base, and passing a free end of the bearing through the through hole to connect with the heat absorbing sheet.

16. The method of claim 15, wherein the free end of the bearing is laser welding to the heat absorbing sheet.

17. The method of claim 14, wherein the heat absorbing plate is rectangular.

18. The method of claim 14, wherein the heat absorbing plate is circular.
